(19) United States
(12) Patent Application Publication
(10) Pub. No.: US 2017/0243916 A1
(43) Pub. Date: Aug. 24, 2017

(54) Capsule Quantum Dot Composition, Light-Emitting Diode, Preparation Methods and Display Apparatus

(71) Applicant: BOE Technology Group Co., Ltd., Beijing (CN)

(72) Inventors: Ming Zhu, Beijing (CN); Jikai Yao, Beijing (CN); Xin Gu, Beijing (CN); Yonglian Qi, Beijing (CN)

(21) Appl. No.: 15/292,887

(22) Filed: Oct. 13, 2016

(30) Foreign Application Priority Data
Feb. 19, 2016 (CN) 201610094470.8

(51) Int. Cl. H01L 27/15; H01L 33/06; C09K 11/02; H01L 33/62; H01L 33/00; H01L 27/12; H01L 33/56

(52) U.S. Cl. CPC H01L 27/156; H01L 27/1214; H01L 33/06; H01L 33/56; H01L 33/62; H01L 33/005; C09K 11/025; H01L 2933/005

(57) ABSTRACT

A capsule Quantum Dot (QD) composition, a light-emitting diode, preparation methods and a display apparatus are provided. The capsule QD composition includes a mesoporous material in submicron or micron order, quantum dots (QDs) adsorbed in pores of the mesoporous material, and an encapsulation material for packaging the QDs in the pores of the mesoporous material.

This application claims priority to and the benefit of Chinese Patent Application No. 201610094470.8 filed on Feb. 19, 2016, which application is incorporated herein in its entirety.

### TECHNICAL FIELD

Embodiments of the present disclosure relate to a capsule Quantum Dot (QD) composition, a light-emitting diode, preparation methods and a display apparatus.

### BACKGROUND

Quantum Dots (QDs) consist of a limited number of atoms, and three dimension sizes are all in nano-meter order of magnitude. The QDs can receive exciting light and generate fluorescent light, and compared with other luminescent materials, the QDs have various advantages, e.g., the QDs show a narrow excitation spectrum and a wide emission spectrum, and by changing the size of the QDs, the emission spectrum of the QDs can be changed. Thus, currently, a QD material has been applied to the technical field of display to improve luminous efficiency and gamut.

### SUMMARY

Embodiments of the present invention provide a capsule Quantum Dot (QD) composition, comprising a mesoporous material in submicron or micron order, quantum dots (QDs) adsorbed in pores of the mesoporous material, and an encapsulation material for encapsulating the QDs in the pores of the mesoporous material.

In one embodiment of the present invention, for example, the mesoporous material is a transparent mesoporous material.

In one embodiment of the present invention, for example, the encapsulation material is a thermosetting resin.

In one embodiment of the present invention, for example, a particle size of the QDs is between 1 nm and 10 nm.

In one embodiment of the present invention, for example, the encapsulation material is a transparent encapsulation material.

Embodiments of the present invention provide a display apparatus, comprising a light-emitting diode, the light-emitting diode comprises a base substrate and a first electrode, a quantum dot (QD) layer and a second electrode which are sequentially arranged on the base substrate, wherein the QD layer comprises the above capsule QD composition; and the QD layer is arranged at a position of each sub-pixel of the display apparatus.

In one embodiment of the present invention, for example, the display apparatus further comprising a thin film transistor arranged at the position of each sub-pixel; and a drain electrode of the thin film transistor is electrically connected with the first electrode.

Embodiments of the present invention provide a preparation method of a capsule Quantum Dot (QD) composition, comprising: mixing a mesoporous material in submicron or micron order with quantum dots (QDs) in a thermosetting resin and stirring uniformly; and slowly heating, carrying out stirring, and after the resin is cured, encapsulating the QDs in pores of the mesoporous material so as to form the capsule QD composition.

In one embodiment of the present invention, for example, in the preparation method, the mesoporous material is a transparent mesoporous material.

In one embodiment of the present invention, for example, in the preparation method, a particle size of the QDs is between 1 nm and 10 nm.

In one embodiment of the present invention, for example, in the preparation method, the thermosetting resin is a transparent thermosetting resin.

Embodiments of the present invention provide a preparation method of a light-emitting diode, comprising sequentially forming a first electrode, a quantum dot (QD) layer and a second electrode on a base substrate, wherein the forming the QD layer includes: uniformly mixing the capsule QD composition prepared by using the above method into a thermosetting resin, and coating the thermosetting resin on the substrate on which the first electrode is formed; and forming the QD layer through exposure and development by adopting a mask.

In one embodiment of the present invention, for example, in the preparation method, the thermosetting resin is a positive photoresist or a negative photoresist.

### BRIEF DESCRIPTION OF THE DRAWINGS

In order to clearly illustrate the technical solution of the embodiments of the disclosure, the drawings of the embodiments will be briefly described in the following, it is obvious that the described drawings are only related to some embodiments of the disclosure and thus are not limitative of the disclosure.

FIG. 1 is a schematic diagram of a relationship between contact time of red Quantum Dot (QD) light and an initiator 369 and fluorescence intensity remaining percentage provided by conventional technique;

FIG. 2 is a structural schematic diagram of a capsule QD composition provided by an embodiment of the present disclosure;

FIG. 3 is a structural schematic diagram of a light-emitting diode provided by an embodiment of the present disclosure;

FIG. 4 is a structural schematic diagram I of a display apparatus provided by an embodiment of the present disclosure;

FIG. 5 is a structural schematic diagram II of the display apparatus provided by an embodiment of the present disclosure;

FIG. 6 is a flow schematic diagram of a preparation method of a capsule QD composition provided by an embodiment of the present disclosure;

FIG. 7 is a flow schematic diagram of a preparation method of a light-emitting diode provided by an embodiment of the present disclosure;

FIG. 8(a) is a schematic diagram I of a preparation process of the light-emitting diode provided by an embodiment of the present disclosure;

FIG. 8(b) is a schematic diagram II of the preparation process of the light-emitting diode provided by an embodiment of the present disclosure; and

FIG. 8(c) is a schematic diagram III of the preparation process of the light-emitting diode provided by an embodiment of the present disclosure.

### REFERENCE SIGNS

10—mesoporous material; 20—quantum dot (QD); 30—encapsulation material; 40—substrate; 50—first electrode; 60—quantum dot (QD) layer; 70—second electrode; 80—thin film transistor; 90—mask; 100—sub-pixel.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

In an application of Quantum Dots (QDs) to form a light-emitting layer, a QD thin film needs to be patterned. In a conventional process, exposure and development as well as printing are employed. For a low accuracy requirement, generally, technologies of silk printing and the like are adopted to implement; and for a high accuracy requirement, an exposure and development technology is adopted. However, a photoinitiator adopted in the exposure and development technological process generally will cause fluorescence quenching, so that luminous efficiency of a prepared QD film layer is reduced such that it cannot be used.

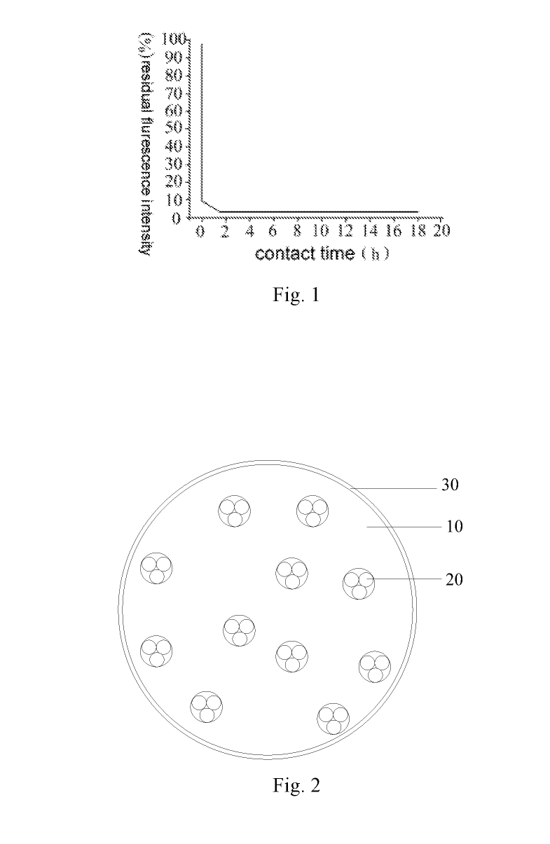

For example, when red QD light is in contact with an initiator 369, as shown in FIG. 1, remaining fluorescence intensity may be reduced to zero in a short time.

An embodiment of the present disclosure provides a capsule QD composition, as shown in FIG. 2, including a mesoporous material 10 in submicron or micron order, QDs 20 adsorbed in pores of the mesoporous material 10, and an encapsulation material 30 for packaging the QDs 20 in the pores of the mesoporous material 10.

The QDs 20 generally are of a sphere or sphere-like shape, and are nano particles consisting of IIB-VIA-group or IIIA-VA-group elements. The QDs 20 are aggregates of atoms and molecules on nano-meter scale, and not only can consist of one type of semiconductor material, e.g., the IIB-VIA-group elements (e.g., cadmium sulfide (CdS), cadmium selenide (CdSe), cadmium telluride (CdTe), zinc selenide (ZnSe) and the like) or the IIIA-VA-group elements (e.g., indium phosphide (InP), indium arsenide (InAs) and the like), but also can consist of two or more types of semiconductor materials. A particle size of the QDs 20 is generally between 1 nm and 10 nm, and electrons and holes are confined by quanta and a continuous energy band structure is changed into a discrete energy level structure with molecular characteristics, so that after the QDs are excited, fluorescent light can be emitted.

It should be noted that firstly, the submicron or micron order mesoporous material 10 is a material which has a porous structure and of which a pore size is in submicron order or micron order. The mesoporous material 10 can be reasonably selected according to the size of the QDs 20 so that more QDs 20 are absorbed into the pores of the mesoporous material 10.

Wherein, the mesoporous material 10 can be a silicon-based mesoporous material, and also can be a non-silicon-based mesoporous material, wherein the silicon-based mesoporous material is narrow in pore size distribution and regular in pore structure; the silicon-based mesoporous material contains a pure silicon mesoporous material and a silicon-based mesoporous material doped with other elements; and the non-silicon-based mesoporous material includes a transition metal oxide, phosphate, sulfide and the like.

Secondly, the QDs 20 have a quantum size effect, and the optical property of the light emitted by the QDs 20 can be controlled by changing the size of the QDs 20. The QDs 20 of which chemical composition and the diameter meet requirements can be reasonably selected according to a required property of the light.

Thirdly, any encapsulation material 30 can be adopted, as long as the encapsulation material 30 for encapsulating the pores of the mesoporous material 10 can encapsulate the pores of the mesoporous material 10. In order to ensure that the light can pass through the encapsulation material 30 and finally emits out, the encapsulation material 30 should be a transparent material.

The embodiment of the present disclosure provides a capsule QD composition, in which the QDs 20 are encapsulated in the pores of the mesoporous material 10 by the encapsulation material 30. As a result, when a patterning process is adopted to form a patterned QD layer, the QDs 20 are not in contact with resin, a solvent and the photoinitiator in light-cured resin. Therefore, the problem of fluorescence quenching caused by contact between the QDs 20 and the photoinitiator is avoided, and the stability of the QDs is ensured.

In order to improve a light emitting rate of the light emitted by the QDs 20 and avoid a shading of the emitting light by the mesoporous material 10, for example, the mesoporous material 10 can be a transparent mesoporous material.

Wherein, the transparent mesoporous material, for example, can be silicon dioxide (SiO₂), porous glass, inorganic silica gel, aerogel, a mesoporous molecular sieve and the like.

Thermosetting resin is easy to prepare and is low in cost, and thus, for example, the encapsulation material 30 may be a thermosetting resin.

The thermosetting resin generally consists of two parts: powder and liquid. A trade name of the powder is dental base acrylic resin powder, and a trade name of the liquid is dental base acrylic resin liquid. The dental base acrylic resin powder comprises methyl methacrylate homopolymerized powder or copolymerized powder, a pigment and the like. The dental base acrylic resin liquid comprises methyl methacrylate, a cross-linking agent (a small quantity), a polymerization inhibitor (a small quantity) and an ultraviolet absorbent (a micro quantity).

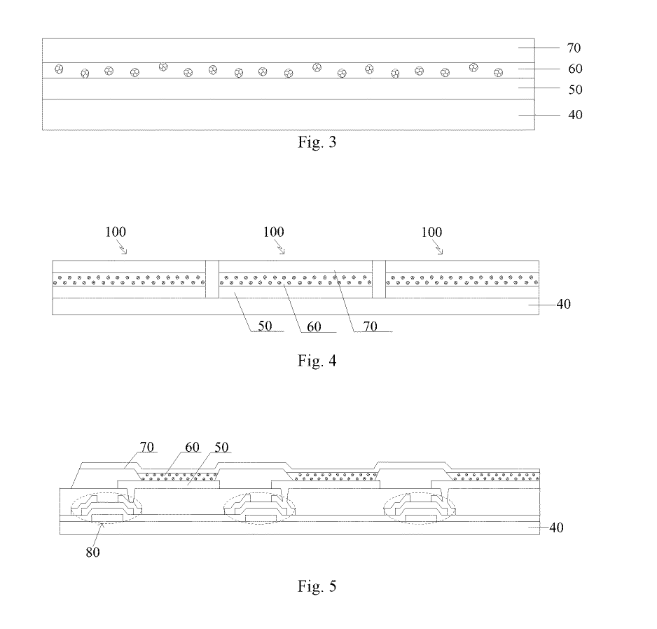

An embodiment of the present disclosure further provides a light-emitting diode, as shown in FIG. 3, including a first electrode 50, a QD layer 60 and a second electrode 70 which are sequentially arranged on a base substrate 40. The QD layer 60 includes the capsule QD composition.

Wherein, the first electrode 50, for example, can be an anode, and correspondingly, the second electrode 70 is a cathode; and the first electrode also can be a cathode, and correspondingly, the second electrode 70 is an anode.

In the embodiment of the present disclosure, the light emitting diode includes the QD layer 60, and the QDs 20 in the QD layer 60 are encapsulated in the pores of the mesoporous material 10 by the encapsulation material 30; and thus, when the patterning process is adopted to form the patterned QD layer 60, the QDs 20 are not in contact with resin, the solvent and the photoinitiator in the light-cured resin. Therefore, fluorescence quenching caused by contact between the QDs 20 and the photoinitiator can be avoided, and stability of the QDs 20 is ensured.

An embodiment of the present disclosure further provides a display apparatus, as shown in FIG. 4, including the light-emitting diode, wherein the QD layer 60 is arranged at a position of each sub-pixel 100 of the display apparatus.

In the embodiment of the present disclosure, the display apparatus, for example, can be any one of products or parts with a display function, such as an organic electroluminescent diode display, a tablet personal computer, a television, a notebook computer and the like.

For example, according to a difference in materials of the first electrode 50 and the second electrode 70, the display apparatus can be classified into a single-sided light emitting type and a double-sided light emitting type. Namely, when the material of one of the first electrode 50 and the second electrode 70 is a non-transparent material, the display apparatus is of the single-sided light emitting type; and when the materials of both the first electrode 50 and the second electrode 70 are transparent materials and/or semi-transparent materials, the display apparatus is of the double-sided light emitting type.

For the display apparatus of the single-sided light emitting type, according to a difference in the materials of the first electrode 50 and the second electrode 70, the display apparatus further can be classified into a top light emitting type and a bottom light emitting type. For example, when the material of the first electrode 50 is a transparent or semi-transparent conducting material and the material of the second electrode 70 is a non-transparent conducting material, light is emitted from the base substrate 40, and thus, the display apparatus can be referred to as the bottom light emitting type display apparatus; and when the material of the first electrode 50 is the non-transparent conducting material and the material of the second electrode 70 is the transparent or the semi-transparent conducting material, light is emitted from the other side opposite to the base substrate 40, and thus, the display apparatus can be referred to the top light emitting type display apparatus.

In the embodiment of the present disclosure, the display apparatus includes the light emitting diode, and the QDs 20 in the light emitting diode are encapsulated in the pores of the mesoporous material 10 by the encapsulation material, and thus, when the patterning process is adopted to form the patterned QD layer 60, the QDs 20 are not in contact with resin, the solvent and the photoinitiator in the light-cured resin. Therefore, fluorescence quenching caused by contact between the QDs 20 and the photoinitiator can be avoided, and stability of the QDs 20 is ensured.

In consideration of defects generated when a passive matrix is applied to a large-size display apparatus, for example, the display apparatus provided by the embodiment of the present disclosure may be an active matrix type display apparatus. As shown in FIG. 5, the display apparatus may further include a thin film transistor 80 arranged at the position of each sub-pixel 100.

The thin film transistor 80 includes a gate electrode, a gate insulating layer, a semiconductor active layer, a source electrode and a drain electrode, wherein the drain electrode is electrically connected with the first electrode 50. On such basis, the display apparatus further includes gate lines, gate line leads (not shown) and the like which are electrically connected with the gate electrode, and data lines, data line leads (not shown) and the like which are electrically connected with the source electrode.

The thin film transistor is a semiconductor unit with the switching characteristic, and may be a top gate type, or may be a bottom gate type.

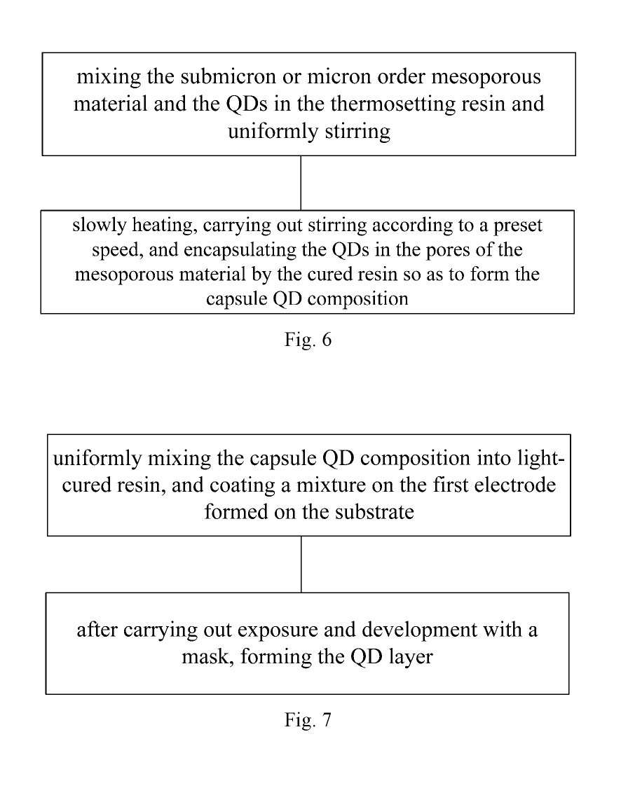

An embodiment of the present disclosure further provides a preparation method of the capsule QD composition as shown in FIG. 6, which includes:

S100: mixing the submicron or micron order mesoporous material 10 and the QDs 20 in the thermosetting resin and uniformly stirring.

By uniformly stirring, the QDs 20 can be sufficiently adsorbed in the pores of the mesoporous material 10.

Wherein, with regard to the amount of the mesoporous material 10, the thermosetting resin and the QDs 20, the only requirement is that the QDs 20 are sufficiently adsorbed in the pores of the mesoporous material 10 and the thermosetting resin can package the pores of the mesoporous material 10.

In order to improve the light emitting rate of the light emitted by the QDs 20 and avoid the shading of the emitting light of the QDs 20 in the middle pores by the mesoporous material 10, for example, the mesoporous material 10 can be a transparent mesoporous material.

The transparent mesoporous material, for example, can be silicon dioxide (SiO₂), porous glass, inorganic silica gel, aerogel, a mesoporous molecular sieve and the like.

S101: slowly heating, carrying out stirring according to a preset speed, and encapsulating the QDs 20 in the pores of the mesoporous material 10 by the cured resin so as to form the capsule QD composition.

The mesoporous material 10 is utilized to adsorb the QDs 20, and in the heating process, the thermosetting resin is cross-linked and cured on the surface of the mesoporous material 10 so as to form a submicron order or micron order dispersed particle (the capsule QD composition).

It should be noted that the stirring speed in the heating process can be reasonably set to obtain a target size of the capsule QD composition.

The embodiment of the present disclosure provides the preparation method of the capsule QD composition. By mixing the mesoporous material 10 and the QDs 20 in the thermosetting resin, adsorbing the QDs 20 in the pores of the mesoporous material 10 and further heating to enable the thermosetting resin to be polymerized and cross-linked, the QDs 20 are encapsulated into the pores of the mesoporous material 10.

An embodiment will describe the preparation method of the capsule QD composition in details as follows:

A silicon dioxide mesoporous material and the QDs 20 are mixed in the thermosetting resin and are sufficiently and uniformly stirred, so that the QDs 20 are sufficiently adsorbed in pores of the silicon dioxide mesoporous material; then, a mixture is slowly heated, and in the heating process, the mixture is stirred according to a certain speed; and finally, the QDs can be encapsulated in the pores of mesoporous silicon dioxide in a cross-linking mode by utilizing the thermosetting resin so as to form the capsule QD composition.

An embodiment of the present disclosure further provides a preparation method of the light emitting diode. As shown in FIG. 3, the preparation method includes: sequentially forming the first electrode 50, the QD layer 60 and the second electrode 70 on the base substrate 40.

Wherein, as shown in FIG. 7, the forming the QD layer 60 includes:

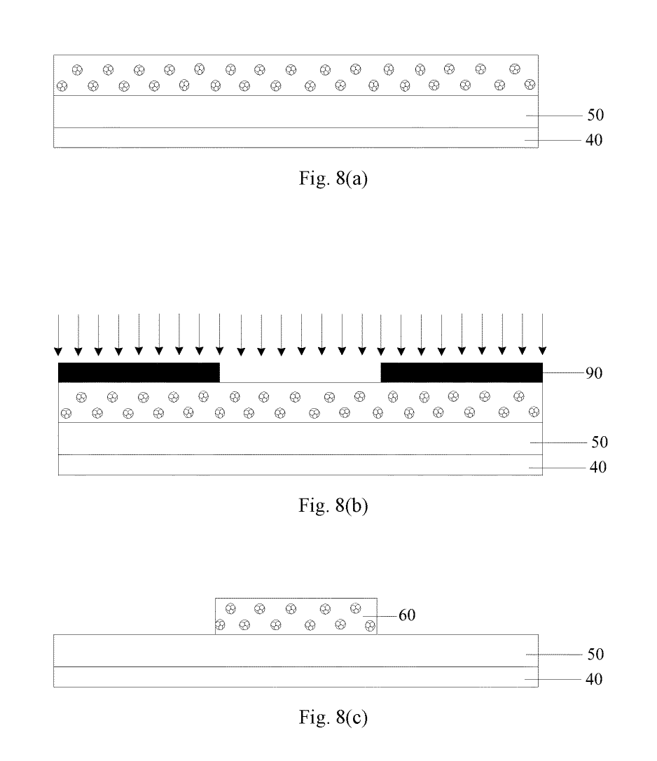

S200: as shown in FIG. 8(a), uniformly mixing the capsule QD composition prepared by the above method into light-cured resin, and coating a mixture on the first electrode 50 formed on the substrate 40.

Wherein, the light-cured resin is a positive photoresist or a negative photoresist. The positive photoresist is developed in an exposure region, and the negative photoresist is not developed in the exposure region.

S201: as shown in FIG. 8(b), after carrying out exposure and development with a mask 90, forming the QD layer 60 as shown in FIG. 8(c).

Wherein, FIG. 8(b) and FIG. 8(c) illustrate by taking the negative photoresist as the light-cured resin for example.

In the embodiment of the present disclosure, the QDs 20 are packaged into the pores of the mesoporous material 10 by the encapsulation material 30, and thus, when the QD layer 60 is prepared, the photoinitiator adopted in the exposure and development process cannot be in contact with the QDs 20, so that stability of the QDs 20 can be ensured.

What are described above is related to the illustrative embodiments of the disclosure only and not limitative to the scope of the disclosure; the scopes of the disclosure are defined by the claims.

The present application claims the priority of the Chinese Patent Application No. 201610094470.8 filed on Feb. 19, 2016, which is incorporated herein by reference as part of the disclosure of the present application.

What is claimed is:

1. A capsule Quantum Dot (QD) composition, comprising a mesoporous material in submicron or micron order, quantum dots (QDs) adsorbed in pores of the mesoporous material, and a encapsulation material for encapsulating the QDs in the pores of the mesoporous material.

2. The capsule QD composition according to claim 1, wherein the mesoporous material is a transparent mesoporous material.

3. The capsule QD composition according to claim 1, wherein the encapsulation material is a thermosetting resin.

4. The capsule QD composition according to claim 1, wherein a particle size of the QDs is between 1 nm and 10 nm.

5. The capsule QD composition according to claim 1, wherein the encapsulation material is a transparent encapsulation material.

6. A display apparatus, comprising a light-emitting diode, wherein the light-emitting diode comprises a base substrate and a first electrode, a quantum dot (QD) layer and a second electrode which are sequentially arranged on the base substrate, wherein the QD layer comprises the capsule QD composition according to claim 1; and
the QD layer is arranged at a position of each sub-pixel of the display apparatus.

7. The display apparatus according to claim 6, further comprising a thin film transistor arranged at the position of each sub-pixel;
wherein a drain electrode of the thin film transistor is electrically connected with the first electrode.

8. A preparation method of a capsule Quantum Dot (QD) composition, comprising:
mixing a mesoporous material in submicron or micron order with quantum dots (QDs) in a thermosetting resin and stirring uniformly; and
heating and stirring mixture of the mesoporous and the QDs, and after the resin is cured, encapsulating the QDs in pores of the mesoporous material so as to form the capsule QD composition.

9. The preparation method according to claim 8, wherein the mesoporous material is a transparent mesoporous material.

10. The preparation method according to claim 8, wherein a particle size of the QDs is between 1 nm and 10 nm.

11. The preparation method according to claim 8, wherein the thermosetting resin is a transparent thermosetting resin.

12. A preparation method of a light-emitting diode, comprising sequentially forming a first electrode, a quantum dot (QD) layer and a second electrode on a base substrate, wherein forming of the QD layer includes:
mixing the capsule QD composition prepared by using the method according to claim 8 into a thermosetting resin, and coating the thermosetting resin on the substrate on which the first electrode is formed; and
forming the QD layer through exposure and development by adopting a mask.

13. The preparation method according to claim 12, wherein the thermosetting resin is a positive photoresist or a negative photoresist.

14. The capsule QD composition according to claim 2, wherein the encapsulation material is a thermosetting resin.

15. The capsule QD composition according to claim 2, wherein a particle size of the QDs is between 1 nm and 10 nm.

16. The capsule QD composition according to claim 2, wherein the encapsulation material is a transparent encapsulation material.
